(19) United States
(12) Patent Application Publication
(10) Pub. No.: US 2026/0063678 A1
(43) Pub. Date: Mar. 5, 2026

(54) CURRENT DETECTION APPARATUS

(71) Applicant: HONDA MOTOR CO., LTD., Tokyo (JP)

(72) Inventors: Kosuke KAJITA, Tokyo (JP); Shotaro KARASUYAMA, Tokyo (JP); Satoshi HASHINO, Tokyo (JP); Takahide SAGAE, Tokyo (JP)

(21) Appl. No.: 19/312,334

(22) Filed: Aug. 28, 2025

(30) Foreign Application Priority Data
Aug. 30, 2024 (JP) 2024-150123

(51) Int. Cl. G01R 15/14; G01R 19/00; G01R 33/00; G01R 33/02

(52) U.S. Cl. CPC G01R 15/148; G01R 19/0092; G01R 33/0005; G01R 33/0206

(57) ABSTRACT

A current detection apparatus includes an α-axis magnetic detection element 8α and a β-axis magnetic detection element 8β. A detection axis Oβ of the element 8β is arranged orthogonal to a first virtual line L1 connecting current lines 6u and 6w, on a surface Pβ that is orthogonal to the current lines 6u and 6w and includes a detection center of the element 8β; the detection center of the element 8β is arranged on a second virtual line L2 that is orthogonal to the line L1 and passes through a midpoint P0 of the line L1; and a second axial distance Dy between the detection center of the element 8β and the line 6u along the line L2 is within a range of an allowable setting error ±Δy with a first axial distance Dx between the current line 6u and the midpoint P0 along the line L1 as the center.

This application is based on and claims the benefit of priority from Japanese Patent Application No. 2024-150123, filed on 30 Aug. 2024, the content of which is incorporated herein by reference.

### BACKGROUND OF THE INVENTION

### Field of the Invention

The present invention relates to a current detection apparatus. More specifically, the present invention relates to a current detection apparatus for detecting a current of each phase of a three-phase motor based on two magnetic detection elements.

### Related Art

Recently, initiatives to realize a low-carbon or carbon-free society have been active, and, for vehicles, research and development for electric vehicles has been also carried out to reduce CO₂ emissions and improve energy efficiency.

As a method for controlling three-phase AC motors mounted on electric vehicles, home appliances (for example, air conditioners and washing machines), and the like, so-called vector control has been widely adopted. In the vector control, a motor control apparatus generates a command signal to an inverter, based on feedback control of a d-axis current and a q-axis current defined on d-q coordinates of a rotating Cartesian coordinate system of the motor.
Patent Document 1: PCT International Publication No. WO2013/058282
Patent Document 2: Chinese Patent Application CN202211040361.X

### SUMMARY OF THE INVENTION

Since feedback control of currents is performed on the d-q coordinates in the motor control apparatus as described above, it is necessary to convert, for example, the U-phase, V-phase, and W-phase currents of a motor detected by such a current detection apparatus as shown in Patent Document 1 to d-axis and q-axis currents. More specifically, in the motor control apparatus, after three phase currents (Iu, Iv, and Iw) detected by the current detection apparatus first are converted to two phase currents (Iα and Iβ) defined in a fixed coordinate system by the Clarke transformation, the two phase currents (Iα and Iβ) are converted to two phase currents (Id and Iq) defined in the d-q coordinate system by the Park transformation using a motor rotation angle θ. Thus, in the vector control using output of a conventional current detection apparatus, it is necessary to perform calculation for converting the three phase currents (Iu, Iv, and Iw) to the two phase currents (Id and Iq) in the motor control apparatus.

Furthermore, Patent Document 2 by the applicant of the present application describes a technology for, by providing two magnetic detection elements at geometrically determined positions around three phase current lines, trying to directly obtain two phase currents (Iα and Iβ) without performing the Clarke transformation by calculation by a computer (such a technology will be hereinafter also referred to as “spatial Clarke transformation”). According to the spatial Clarke transformation as above, it is possible to reduce the number of magnetic detection elements and reduce a calculation load on a computer in comparison with the conventional transformation.

In Patent Document 2, however, influence of positional deviation of the magnetic detection elements relative to each phase current line is not sufficiently considered. That is, in the spatial Clarke transformation technology shown in Patent Document 2, when the installation position of a magnetic detection element deviates from the initial ideal installation position, a relative position of the magnetic detection element relative to each phase current line also deviates, and, therefore, it is thought that the influence of the positional deviation is large.

An object of the present invention is to provide a current detection apparatus for three-phase motor with high toughness of magnetic detection elements against positional deviation relative to each phase current line and, therefore, contribute to improvement of energy efficiency.

(1) A current detection apparatus according to the present invention (for example, a current detection apparatus 3 described later) is a current detection apparatus for detecting currents flowing through a first phase current line (for example, a U-phase current line 6u described later), a second phase current line (for example, a V-phase current line 6v described later), and a third phase current line (for example, a W-phase current line 6w described later) of a three-phase motor (for example, a motor M described later), the current detection apparatus including: an α-axis magnetic detection element (for example, an α-axis magnetic detection element 8α described later) provided around the first, second, and third phase current lines; and a β-axis magnetic detection element (for example, a β-axis magnetic detection element 8β described later) provided around the first and third phase current lines, wherein a detection axis (for example, a detection axis Oβ described later) of the β-axis magnetic detection element is arranged orthogonal to a first virtual line (for example, a first virtual line L1 described later) connecting the first and third phase current lines, on a β-axis element arrangement surface (for example, a β-axis element arrangement surface Pβ or Pβ′ described later) that is orthogonal to both of the first and third phase current lines and includes a detection center of the β-axis magnetic detection element; the detection center of the β-axis magnetic detection element is arranged on a second virtual line (for example, a second virtual line L2 described later) that is orthogonal to the first virtual line and passes through a midpoint (for example, a midpoint P0 described later) of the first virtual line; and a distance between the detection center of the β-axis magnetic detection element and the first phase current line along the second virtual line (for example, a second axial distance Dy described later) is within a predetermined allowable setting error range (for example, an allowable setting error ±Δy described later) with a distance between the first phase current line and the midpoint along the first virtual line (for example, a first axial distance Dx described later) as a center.

(2) A current detection apparatus according to the present invention (for example, the current detection apparatus 3 described later) is a current detection apparatus for detecting currents flowing through a first phase current line (for example, the U-phase current line 6u described later), a second phase current line (for example, the V-phase current line 6v described later), and a third phase current line (for example, the W-phase current line 6w described later) of a three-phase motor (for example, the motor M described later), the current detection apparatus including: an α-axis magnetic detection element (for example, the α-axis magnetic detection element 8α described later) provided around the first, second, and third phase current lines; and a β-axis magnetic detection element (for example, the β-axis magnetic detection element 8β described later) provided around the first and third phase current lines, wherein a detection axis (for example, the detection axis Oβ described later) of the β-axis magnetic detection element is arranged orthogonal to a first virtual line (for example, the first virtual line L1 described later) connecting the first and third phase current lines, on a β-axis element arrangement surface (for example, the β-axis element arrangement surface Pβ or Pβ′ described later) that is orthogonal to both of the first and third phase current lines and includes a detection center of the β-axis magnetic detection element; the detection center of the β-axis magnetic detection element is arranged within a predetermined allowable setting error range (for example, the allowable setting error ±Δy described later) with such a position that a magnetic sensitivity coefficient (for example, a magnetic sensitivity coefficient k_{βu} described later) of the β-axis magnetic detection element for the first phase current line becomes a maximum or minimum value as a center, on a second virtual line (for example, the second virtual line L2 described later) that is orthogonal to the first virtual line and passes through a midpoint (for example, the midpoint P0 described later) of the first virtual line.

(3) In this case, it is preferable that a detection center of the α-axis magnetic detection element is arranged within an α-axis element arrangement surface that is orthogonal to the first, second, and third phase current lines and is different from the β-axis element arrangement surface (for example, an α-axis element arrangement surface Pα described later).

(4) In this case, it is preferable that the α-axis magnetic detection element and the β-axis magnetic detection element are integrated.

(1) A current detection apparatus according to the present invention includes an α-axis magnetic detection element provided around three phase current lines and a β-axis magnetic detection element provided around at least two of the three phase current lines (first and third phase current lines), and detects currents flowing through the three current lines based on output values of the two magnetic detection elements. Furthermore, in the present invention, a detection axis of the β-axis magnetic detection element is arranged orthogonal to a first virtual line connecting the first and third phase current lines, on a β-axis element arrangement surface that is orthogonal to both of the two phase current lines and includes a detection center of the β-axis magnetic detection element. Furthermore, in the present invention, the detection center of the β-axis magnetic detection element is arranged on a second virtual line that is orthogonal to the first virtual line and passes through a midpoint of the first virtual line, that is, at a position at equal distances from the first and third phase current lines. Especially, in the present invention, a distance between the detection center of the β-axis magnetic detection element and the first phase current line along the second virtual line (hereinafter also referred to as “a second axial distance” between the β-axis magnetic detection element and the first phase current line) is set to be within a predetermined allowable setting error range with a distance between the detection center of the β-axis magnetic detection element and the first phase current line along the first virtual line (hereinafter also referred to as “a first axial distance” between the β-axis magnetic detection element and the first phase current line) as the center. As described later with reference to FIGS. 4 and 5, when the detection center of the β-axis magnetic detection element is set at such a position that the first axial distance and the second axial distance are approximately equal, both of change directions of the magnetic sensitivity coefficient of the β-axis magnetic detection element for the first phase current line and the magnetic sensitivity coefficient of the β-axis magnetic detection element for the third phase current line due to positional deviation of the β-axis magnetic detection element along the first virtual line are toward the 0 side. Therefore, according to the present invention, it is possible to improve toughness of the β-axis magnetic detection element against positional deviation along the first virtual line relative to the first and third phase current lines and, therefore, contribute to improvement of energy efficiency.

(2) In a current detection apparatus according to the present invention, a detection center of a β-axis magnetic detection element is arranged on a second virtual line that is orthogonal to a first virtual line and passes through a midpoint of the first virtual line, that is, at a position at equal distances from first and third phase current lines, similarly to the invention of (1) above. Especially, in the present invention, the detection center of the β-axis magnetic detection element is arranged within a predetermined allowable setting error range with such a position that a magnetic sensitivity coefficient of the β-axis magnetic detection element for the first phase current line becomes a maximum or minimum value as the center, on the second virtual line. As described later with reference to FIGS. 4 and 5, when the detection center of the β-axis magnetic detection element is set near such a position that the magnetic sensitivity coefficient of the β-axis magnetic detection element for the first phase current line becomes the maximum value or the minimum value, on the second virtual line, both of change directions of the magnetic sensitivity coefficient of the β-axis magnetic detection element for the first phase current line and the magnetic sensitivity coefficient of the β-axis magnetic detection element for the third phase current line due to positional deviation of the β-axis magnetic detection element along the first virtual line are toward the 0 side. Therefore, according to the present invention, it is possible to improve toughness of the β-axis magnetic detection element against positional deviation along the first virtual line relative to the first and third phase current lines and, therefore, contribute to improvement of energy efficiency.

(3) In the present invention, a detection center of the α-axis magnetic detection element is arranged within the α-axis element arrangement surface that is orthogonal to the first, second, and third phase current lines and is different from the β-axis element arrangement surface. Therefore, according to the present invention, it is possible to cause the output value of the α-axis magnetic detection element to be proportional to an α-phase current value which is obtained by combining currents flowing through the first, second, and third phase current lines at a determined ratio by the Clarke transformation. Furthermore, in the present invention, the detection center of the β-axis magnetic detection element is arranged within the β-axis element arrangement surface that is orthogonal to the first and third phase current lines and is different from the α-axis element arrangement surface. Therefore, according to the present invention, it is possible to cause the output value of the β-axis magnetic detection element to be proportional to a β-phase current value which is obtained by combining currents flowing through the first and third phase current lines at a determined ratio by the Clarke transformation and is orthogonal to the α-phase current value.

(4) In the present invention, by integrating the α-axis magnetic detection element and the β-axis magnetic detection element, it is possible to cause positional deviation amounts of the α-axis and β-axis magnetic detection elements relative to each phase current line to be equal. Furthermore, as described later with reference to FIGS. 7 and 8, in the state in which the α-axis and β-axis magnetic detection elements are integrated, variation in the phase error between the output values of the α-axis and β-axis magnetic detection elements due to positional deviation of the detection centers of the α-axis and β-axis magnetic detection elements along the first virtual line is minimized when the second axial distance and the first axial distance between the detection centers of the α-axis and β-axis magnetic detection elements and the first phase current line are caused to be approximately equal. Therefore, according to the present invention, it is possible to improve toughness of the α-axis and β-axis magnetic detection elements against positional deviation along the first virtual line relative to the first, second, and third phase current lines.

### BRIEF DESCRIPTION OF THE DRAWINGS

FIG. 1 is a diagram showing a configuration of a current detection apparatus according to a first embodiment of the present invention and an electric vehicle equipped with the current detection apparatus;

FIG. 2 is a side view of three phase current lines, and an α-axis element arrangement surface and a β-axis element arrangement surface that are orthogonal to the phase current lines;

FIG. 3 is a diagram schematically showing an example of arrangement of the three phase current lines and an α-axis magnetic detection element on the α-axis element arrangement surface;

FIG. 4 is a diagram schematically showing an example of arrangement of two phase current lines and the β-axis magnetic detection element on the β-axis element arrangement surface;

FIG. 5 is a diagram showing changes in magnetic sensitivity coefficients of the β-axis magnetic detection element for U-phase and W-phase current lines, respectively, due to change in a first axial distance;

FIG. 6 is a diagram schematically showing an example of arrangement of the three phase current lines and the β-axis magnetic detection element on the β-axis element arrangement surface according to a modification of the first embodiment;

FIG. 7 is a diagram schematically showing a configuration of a sensor unit according to a second embodiment of the present invention; and

FIG. 8 is a diagram showing a relationship between a positional deviation amount of detection centers of the two magnetic detection elements and phase error between output values of the two magnetic detection elements.

### DETAILED DESCRIPTION OF THE INVENTION

### First Embodiment

A description will be made below on a current detection apparatus according to a first embodiment of the present invention and an electric vehicle mounted with the current detection apparatus with reference to drawings.

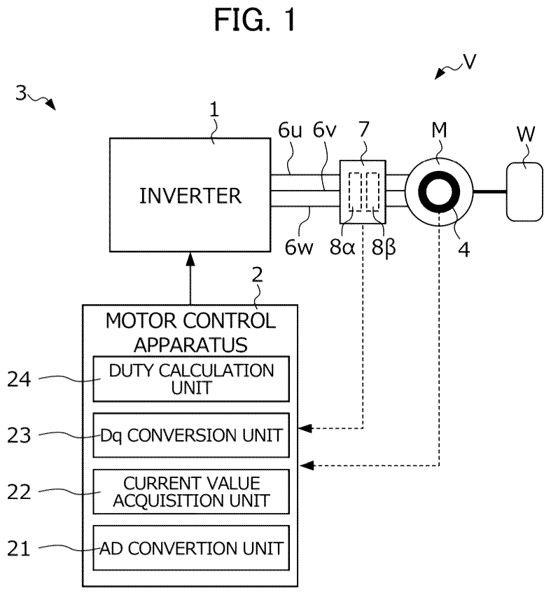

FIG. 1 is a diagram showing a configuration of a current detection apparatus 3 according to the present embodiment and an electric vehicle V equipped with the current detection apparatus 3. Note that, though the description will be made on the case where the current detection apparatus 3 is mounted on the electric vehicle V, the present invention is not limited thereto. The current detection apparatus 3 can be mounted on anything that controls the three-phase motor based on vector control, such as an air conditioner or a washing machine, in addition to the electric vehicle V.

The electric vehicle V includes a three-phase AC motor M (hereinafter simply referred to as “the motor M”), a drive wheel W coupled with the output shaft of the motor M via a power transmission mechanism not shown, an inverter 1 that connects a battery not shown and the motor M, a sensor unit 7 that generates a signal corresponding to a current that flows through the motor M, a resolver 4 that detects a rotation position of the motor M, and a motor control apparatus 2 that controls the inverter 1 based on detection signals of the sensor unit 7 and the resolver 4.

The inverter 1 is, for example, a PWM inverter using pulse width modulation, which is equipped with a bridge circuit configured by bridge connection of a plurality of switching elements (for example, IGBT's), and has a function of converting DC power and AC power. The inverter 1 is connected to the battery on the DC input/output side and connected to each of the U-phase, V-phase, and W-phase coils of the motor M on the AC input/output side, and converts power between the battery and the motor M. By performing on/off driving of the switching element of each phase according to a gate drive signal, which is generated from a gate drive circuit not shown at a predetermine timing, the inverter 1 converts DC power supplied from the battery to AC power to supply the AC power to the motor M or converts AC power supplied from the motor M to DC power to supply the DC power to the battery.

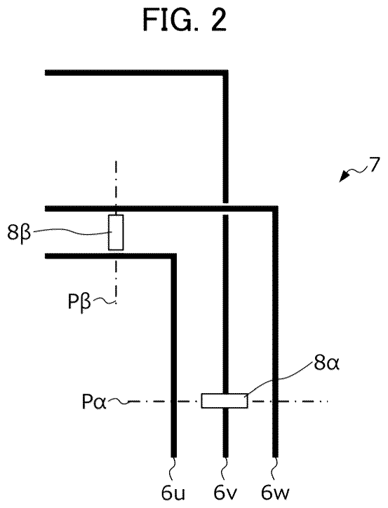

The sensor unit 7 includes an α-axis magnetic detection element 8α provided around three phase current lines (a U-phase current line 6u, a V-phase current line 6v, and a W-phase current line 6w) that connect the motor M and the inverter 1, and a β-axis magnetic detection element 8β provided around at least the two phase current lines 6u and 6w among the three phase current lines 6u, 6v, and 6w. The magnetic detection elements 8α and 8β generate detection signals corresponding to components of the magnetic flux density of a magnetic field generated by currents flowing through the phase current lines 6u, 6v, and 6w, along their respective detection axes. Note that a specific example of arrangement of the α-axis and β-axis magnetic detection elements 8α and 8β, and the three phase current lines 6u, 6v, and 6w will be described later with reference to FIGS. 2 to 6.

The motor control apparatus 2 is a computer that generates a drive signal to the gate drive circuit of the inverter 1 by performing vector control based on detection signals from the two magnetic detection elements 8α and 8β and the resolver 4 and inputs the drive signal to the gate drive circuit.

In the motor control apparatus 2, an AD conversion unit 21, a current value acquisition unit 22, a dq conversion unit 23, and a duty calculation unit 24 are configured as modules related to execution of the vector control described above.

By performing AD conversion of detection signals of the α-axis and β-axis magnetic detection elements 8α and 8β, the AD conversion unit 21 acquires output values (S_{α} and S_{β}) of the α-axis and β-axis magnetic detection elements 8α and 8β.

Based on the output values (S_{α} and S_{β}) of the α-axis and β-axis magnetic detection elements 8α and 8β acquired by the AD conversion unit 21, the current value acquisition unit 22 acquires an α-phase current value I_{α} and a β-phase current value Is corresponding to two phase currents, which are obtained by performing the Clarke transformation of three phase currents (Iu, Iv, and Iw) as shown by Formula (1-1) below. Note that, though, in the present embodiment, the description will be made on a case where the current value acquisition unit 22 acquires the output values (S_{α} and S_{β}) of the α-axis and β-axis magnetic detection elements 8α and 8β as α-phase and β-phase current values (I_{α}, I_{β}) as they are, as shown by Formula (1-2) below, the present invention is not limited thereto. For example, as described in Patent Application No. 2024-017417 by the applicant of the present application, the current value acquisition unit 22 may acquire values obtained by multiplying the output values (S_{α} and S_{β}) of the α-axis and β-axis magnetic detection elements 8α and 8β by predetermined α-phase and β-phase gains G_{α} and G_{β}, respectively, as the α-phase current value I_{α} and the β-phase current value I_{β}. Note that, in this case, values of the α-phase and β-phase gains (G_{α} and G_{β}) are set so that amplitudes of the α-phase and β-phase current values (I_{α}, I_{β}) are equal. Therefore, in the present embodiment, the current detection apparatus 3 that detects currents flowing through the three phase current lines 6u, 6v, and 6w of the motor M is configured with the two magnetic detection elements 8_{α} and 8_{β}, the AD conversion unit 21, and the current value acquisition unit 22.

$$( \begin{matrix}{I}_{α} \\ {I}_{β}\end{matrix} ) ∝ ( \begin{matrix}- 1 / 2 & 1 & - 1 / 2 \\ \sqrt{3} / 2 & 0 & - \sqrt{3} / 2\end{matrix} ) ( \begin{matrix}I u \\ I ν \\ I w\end{matrix} ) \qquad ( 1 - 1 )$$

$$( \begin{matrix}{I}_{α} \\ {I}_{β}\end{matrix} ) = ( \begin{matrix}{S}_{α} \\ {S}_{β}\end{matrix} ) \qquad ( 1 - 2 )$$

By performing known calculation using the current values (I_{α}, I_{β}) acquired by the current value acquisition unit 22 and a detection signal of the resolver 4, the dq conversion unit 23 calculates a d-axis current Id and a q-axis current Iq.

By acquiring a d-axis current command Idc and a q-axis current command Iqc corresponding to driving force required by a driver and performing feedback control based on deviations (Idc-Id, Iqc-Iq) of the current values, the duty calculation unit 24 generates a drive signal for the gate drive circuit of the inverter 1 so as to realize the driving force required by the driver and inputs the driving force to the gate drive circuit.

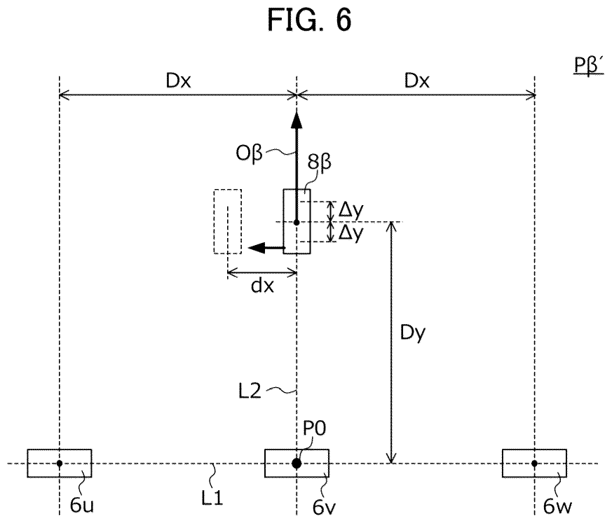

FIG. 2 is a side view of the three phase current lines 6u, 6v, and 6w and an α-axis element arrangement surface Pα and a β-axis element arrangement surface Pβ that are orthogonal to the phase current lines. In the present embodiment, the description will be made on a case where, as shown in FIG. 2, the detection center of the α-axis magnetic detection element 8α is provided within the virtual α-axis element arrangement surface Pα that is orthogonal to the three phase current lines 6u, 6v, and 6w, and the detection center of the β-axis magnetic detection element 8β is provided within the β-axis element arrangement surface Pβ that is orthogonal to at least the two phase current lines 6u and 6w and is different from the α-axis element arrangement surface Pα. That is, the description will be made below on a case where the distance between the β-axis magnetic detection element 8β and the V-phase current line 6v is sufficiently longer than the distances between the β-axis magnetic detection element 8β and the other two phase current lines 6u and 6w. The present invention, however, is not limited thereto. As for a case where the β-axis magnetic detection element 8β is arranged near the three phase current lines 6u, 6v, and 6w similarly to the α-axis magnetic detection element 8α, it will be described later as a modification with reference to FIG. 6.

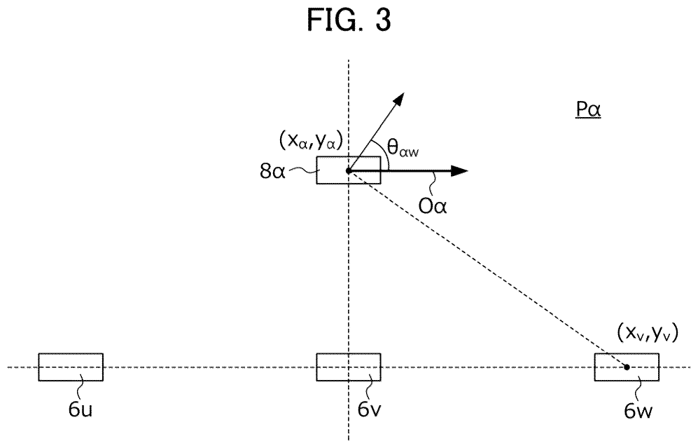

FIG. 3 is a diagram schematically showing an example of arrangement of the three phase current lines 6u, 6v, and 6w and the α-axis magnetic detection element 8α on the α-axis element arrangement surface Pα. Note that, though FIG. 3 shows a case where the three phase current lines 6u, 6v, and 6w are linearly arranged in that order at equal intervals within the α-axis element arrangement surface Pα, the present invention is not limited thereto. When the three phase current lines 6u, 6v, and 6w are arranged as above, a detection axis Oα of the α-axis magnetic detection element 8α is arranged parallel to a virtual line that passes through the three phase current lines 6u, 6v, and 6w as shown in FIG. 3. Furthermore, the detection center of the α-axis magnetic detection element 8α is arranged at a predetermined position on a virtual line that is orthogonal to a virtual line passing through the three phase current lines 6u, 6v, and 6w and passes through the V-phase current line 6v as shown in FIG. 3.

Here, the output value S_{α} of the α-axis magnetic detection element 8α is expressed by Formula (2-1) below when magnetic sensitivity coefficients (k_{αu}, k_{αv}, and k_{αw}) of the α-axis magnetic detection element 8α for the phase current lines 6u, 6v, and 6w, respectively, are used. The magnetic sensitivity coefficients (k_{αu}, k_{αv}, and k_{αw}) are values determined by relative positions relative to the three phase current lines 6u, 6v, and 6w of the α-axis magnetic detection element 8α, respectively, and the direction of the detection axis. More specifically, for example, the magnetic sensitivity coefficient k_{αw} of the α-axis magnetic detection element 8α for the W-phase current line 6w is defined by Formula (2-2) below according to Ampere's Law. In Formula (2-2) below, μ represents magnetic permeability. Furthermore, in Formula (2-2) below, Owa indicates an angle formed by a magnetic field vector of the W-phase current line 6w and the detection axis of the α-axis magnetic detection element 8α, (x_{α}, y_{α}) indicates coordinate values of the α-axis magnetic detection element 8α on the α-axis element arrangement surface Pα; and (x_{w}, y_{w}) indicates coordinate values of the W-phase current line 6w on the α-axis element arrangement surface Pα. Note that, since the other magnetic sensitivity coefficients (k_{αu} and k_{αw}) are also defined based on Ampere's Law similarly to Formula (2-2) below, detailed description thereof will be omitted. As described above, the magnetic sensitivity coefficients (k_{αu}, k_{αv}, and k_{αw}) are determined by relative positions relative to the three phase current lines 6u, 6v, and 6w of the α-axis magnetic detection element 8α and the direction of the detection axis.

$${S}_{α} ∝ [ \begin{matrix}{k}_{α u} & {k}_{α v} & {k}_{α w}\end{matrix} ] [ \begin{matrix}{I}_{u} \\ {I}_{v} \\ {I}_{w}\end{matrix} ] \qquad ( 2 - 1 )$$

$${k}_{α w} = \frac{μ cos {θ}_{α w}}{2 π \sqrt{{( {x}_{w} - {x}_{α} )}^{2} + {( {y}_{w} - {y}_{α} )}^{2}}} \qquad ( 2 - 2 )$$

Furthermore, the detection center of the α-axis magnetic detection element 8α is arranged at such a position that Formula (3) for the magnetic sensitivity coefficients (k_{αu}, k_{αv}, and k_{αw}) holds on the α-axis element arrangement surface Pα. Thereby, it is possible to cause the output value S_{α} of the α-axis magnetic detection element 8α to be proportional to the α-phase current values I_{α}.

$$[ \begin{matrix}{k}_{α u} \\ {k}_{α v} \\ {k}_{α w}\end{matrix} ] ∝ [ \begin{matrix}- 1 / 2 \\ 1 \\ - 1 / 2\end{matrix} ] \qquad ( 3 )$$

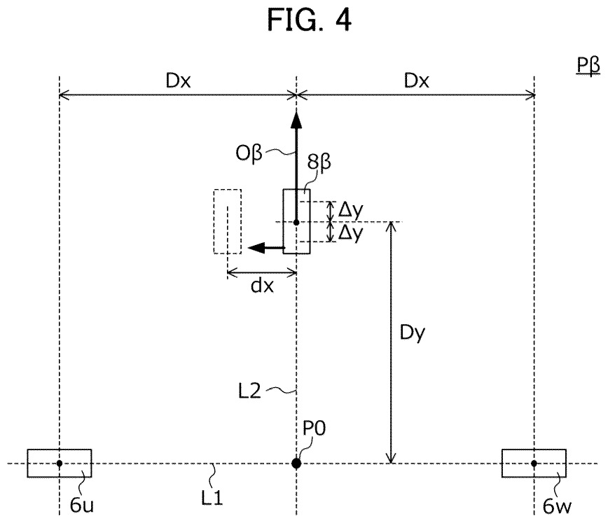

FIG. 4 is a diagram schematically showing an example of arrangement of the two phase current lines 6u and 6v and the β-axis magnetic detection element 8β on the β-axis element arrangement surface Pβ.

As shown in FIG. 4, a detection axis Oβ of the β-axis magnetic detection element 8β is arranged orthogonal to a first virtual line L1 connecting the U-phase current line 6u and the W-phase current line 6w, on the β-axis element arrangement surface Pβ that is orthogonal to both of the U-phase current line 6u and the W-phase current line 6w and includes the detection center of the β-axis magnetic detection element 8β. Furthermore, the detection center of the β-axis magnetic detection element Pβ is arranged on a second virtual line L2 that is orthogonal to the first virtual line L1 and passes through a midpoint Pβ of the first virtual line L1. Thereby, it is possible to cause the output value S_{β} of the β-axis magnetic detection element 8β to be proportional to the β-phase current values I_{β} as shown by Formula (4) below.

$${S}_{β} ∝ [ \begin{matrix}\sqrt{3} / 2 & 0 & - \sqrt{3} / 2\end{matrix} ] [ \begin{matrix}{I}_{u} \\ {I}_{v} \\ {I}_{w}\end{matrix} ] \qquad ( 4 )$$

Hereinafter, a distance between the detection center of the β-axis magnetic detection element 8β and the U-phase current line 6u (or the W-phase current line 6w) along the first virtual line L1 on the β-axis element arrangement surface Pβ will be referred to as a first axial distance and indicated by “Dx”. Furthermore, a distance between the detection center of the β-axis magnetic detection element 8β and the U-phase current line 6u (or the W-phase current line 6w) along the second virtual line L2 on the β-axis element arrangement surface Pβ will be referred to as a second axial distance and indicated by “Dy”.

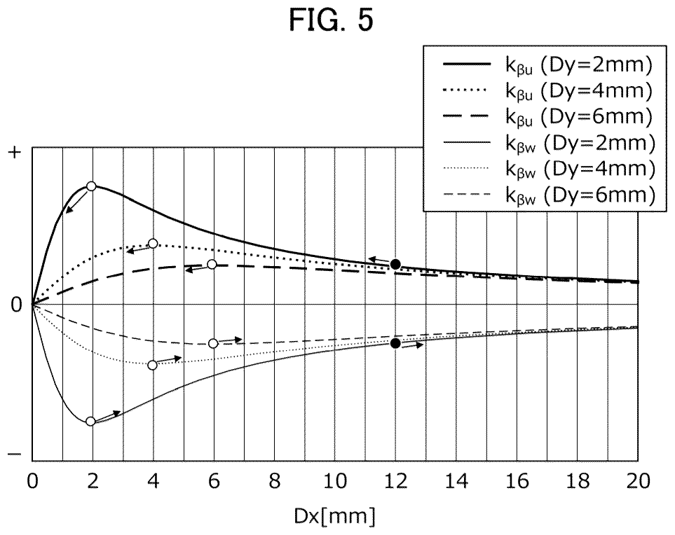

FIG. 5 is a diagram showing changes in magnetic sensitivity coefficients k_{βu} and k_{βw} of the β-axis magnetic detection element 8β for the phase current lines 6u and 6w, respectively, due to change in the first axial distance Dx. In FIG. 5, the magnetic sensitivity coefficient k_{βu} of the β-axis magnetic detection element 8β for the U-phase current line 6u is indicated by thick lines, and the magnetic sensitivity coefficient k_{βw} of the β-axis magnetic detection element 8β for the W-phase current line 6w is indicated by thin lines. Furthermore, In FIG. 5, the magnetic sensitivity coefficients k_{βu} and k_{βw} when the second axial distance Dy is set to 2 [mm], 4 [mm], and 6 [mm] are shown with different line types.

As shown in FIG. 5, though the magnetic sensitivity coefficients k_{βu} and k_{βw} have opposite signs, the absolute values are the same because the distances between the β-axis magnetic detection element 8β and the phase current lines 6u and 6w are the same. When the second axial distance Dy is increased, the distances between the β-axis magnetic detection element 8β and the phase current lines 6u and 6w also increase, and, therefore, the magnetic sensitivity coefficients k_{βu} and k_{βw} approach 0.

Furthermore, when the first axial distance Dx is changed between 0 [mm] and 20 [mm], the magnetic sensitivity coefficient k_{βu} behaves forming an upward convex, and the magnetic sensitivity coefficient k_{βw} behaves forming a downward convex. More specifically, when the second axial distance Dy is set to 2 [mm], the magnetic sensitivity coefficient k_{βu} and the magnetic sensitivity coefficient k_{βw} reach the maximum value and the minimum value, respectively, when the first axial distance Dx is approximately 2 [mm]. Furthermore, when the second axial distance Dy is set to 4 [mm], the magnetic sensitivity coefficient k_{βu} and the magnetic sensitivity coefficient k_{βw} reach the maximum value and the minimum value, respectively, when the first axial distance Dx is approximately 4 [mm]. Furthermore, when the second axial distance Dy is set to 6 [mm], the magnetic sensitivity coefficient k_{βu} and the magnetic sensitivity coefficient k_{βw} reach the maximum value and the minimum value, respectively, when the first axial distance Dx is approximately 6 [mm]. Therefore, the magnetic sensitivity coefficient k_{αu} reaches the maximum value when the first axial distance Dx and the second axial distance Dy between the β-axis magnetic detection element 8β and the U-phase current line 6u are approximately equal. Furthermore, the magnetic sensitivity coefficient k_{βw} reaches the minimum value when the first axial distance Dx and the second axial distance Dy between the β-axis magnetic detection element 8β and the W-phase current line 6w are approximately equal.

Here, it is assumed that, as shown in FIG. 4, the detection center of the β-axis magnetic detection element 8β has deviated from the second virtual line L2 toward the U-phase current line 6u side along a direction orthogonal to the second virtual line L2 by a distance dx. When the β-axis magnetic detection element 8β shifts to the U-phase current line 6u side, the first axial distance Dx between the β-axis magnetic detection element 8β and the U-phase current line 6u decreases, while the first axial distance Dx between the β-axis magnetic detection element 8β and the W-phase current line 6w increases.

Therefore, if the positional deviation of the β-axis magnetic detection element 8β described above occurs in the state in which the second axial distance Dy is approximately equal to the first axial distance Dx, in other words, in the state in which the second axial distance Dy is set to such a position that the magnetic sensitivity coefficient k_{βu} is the maximum value, and the magnetic sensitivity coefficient k_{βw} is the minimum value as indicated by white circles in FIG. 5, then the magnetic sensitivity coefficient k_{βu}, which is a positive value, decreases toward the 0 side, and the magnetic sensitivity coefficient k_{βw}, which is a negative value, increases toward the 0 side. Furthermore, when the second axial distance Dy is set to such a length that the magnetic sensitivity coefficients k_{βu} and k_{βw} become extreme values, changes in the magnetic sensitivity coefficients k_{βu} and k_{βw} due to minute positional deviation is also small. In comparison, if the positional deviation of the β-axis magnetic detection element 8β described above occurs in a state in which the second axial distance Dy is set to a length that is significantly different from the first axial distance Dx, in other words, in a state in which the second axial distance Dy is set to a length that is significantly different from the length at which the magnetic sensitivity coefficients k_{βu} and k_{βw} become extreme values as shown by black circles in FIG. 5, then the magnetic sensitivity coefficient k_{βu}, which is a positive value, increases in a direction away from 0, and the magnetic sensitivity coefficient k_{βw}, which is a negative value, increases toward the 0 side.

Since the magnetic sensitivity coefficients k_{βu} and k_{βw} of the β-axis magnetic detection element 8β for the phase current lines 6u and 6w have the characteristics described above for positional deviation, it can be said that it is possible to, by causing the second axial distance Dy to be approximately equal to the first axial distance Dx, minimize the phase error of the output value S_{β} of the β-axis magnetic detection element 8β which occurs due to positional deviation. Here, the phase error of the output value S_{β} of the β-axis magnetic detection element 8β refers to a phase difference between the output value S_{β} of the β-axis magnetic detection element 8β before positional deviation occurs and the output value Se of the β-axis magnetic detection element 8β after the positional deviation occurs. Therefore, the second axial distance Dy between the β-axis magnetic detection element 8β and the U-phase current line 6u (or the W-phase current line 6w) is set within a range of a predetermined allowable setting error ±Δy with the first axial distance Dx between the β-axis magnetic detection element 8β and the U-phase current line 6u (or the W-phase current line 6w) as the center (Dx−Δy≤Dy≤Dx+Δy). In other words, the detection center of the β-axis magnetic detection element 8β is arranged within a range of an allowable setting error ±Δy with such a position that the magnetic sensitivity coefficient k_{βu} (or the magnetic sensitivity coefficient k_{βw}) of the β-axis magnetic detection element 8β for the U-phase current line 6u (or the W-phase current line 6w) becomes the maximum value (or the minimum value) as the center, on the second virtual line L2. Here, the width Δy of the allowable setting error is set to a length less than the second axial distance Dy (Δy≤Dy), more specifically, to a length less than 1/10 of the second axial distance Dy (Δy≤Dy/10).

According to the current detection apparatus 3 according to the present embodiment, the following effects are obtained:
(1) The current detection apparatus 3 includes the α-axis magnetic detection element 8α provided around the three phase current lines 6u, 6v, and 6w and the β-axis magnetic detection element 8β provided around the two phase current lines 6u and 6w, and detects currents flowing through the three phase current lines 6u, 6v, and 6w based on the output values (S_{α} and S_{β}) of the two magnetic detection elements 8α and 8β. Further, in the current detection apparatus 3, the detection axis O_{β} of the β-axis magnetic detection element 8β is arranged orthogonal to the first virtual line L1 connecting the U-phase current line 6u and the W-phase current line 6w, on the β-axis element arrangement surface Pβ that is orthogonal to both of the two phase current lines 6u and 6w and includes the detection center of the β-axis magnetic detection element 8β. Furthermore, in the current detection apparatus 3, the detection center of the β-axis magnetic detection element 8β is arranged on the second virtual line L2 that is orthogonal to the first virtual line L1 and passes through the midpoint P0 of the first virtual line L1, that is, at a position at equal distances from the U-phase current line 6u and the W-phase current line 6w. Especially, in the present embodiment, the second axial distance Dy between the β-axis magnetic detection element 8β and the U-phase current line 6u (or the W-phase current line 6w) is set within the range of the predetermined allowable setting error ±Δy with the first axial distance Dx between the β-axis magnetic detection element 8β and the U-phase current line 6u (or the W-phase current line 6w) as the center. As described above, when the detection center of the β-axis magnetic detection element 8β is set at such a position that the first axial distance Dx and the second axial distance Dy are approximately equal, both of change directions of the magnetic sensitivity coefficient k_{βu} of the β-axis magnetic detection element 8β for the U-phase current line 6u and the magnetic sensitivity coefficient k_{βw} of the β-axis magnetic detection element 8β for the W-phase current line 6w due to positional deviation of the β-axis magnetic detection element 8β along the first virtual line L1 are toward the 0 side. Therefore, according to the current detection apparatus 3, it is possible to improve toughness of the β-axis magnetic detection element 8β against positional deviation along the first virtual line L1 relative to the U-phase current line 6u and the W-phase current line 6w and, therefore, contribute to improvement of energy efficiency.
(2) In the present embodiment, the detection center of the β-axis magnetic detection element 8β is arranged within the range of the predetermined allowable setting error ±Δy with such a position that the magnetic sensitivity coefficient k_{βu} (or the magnetic sensitivity coefficient k_{βw}) of the β-axis magnetic detection element 8β for the U-phase current line 6u (or the W-phase current line 6w) becomes the maximum value (or the minimum value) as the center, on the second virtual line L2. As described above, when the detection center of the β-axis magnetic detection element 8β is set near such a position that the magnetic sensitivity coefficient k_{βu} (or the magnetic sensitivity coefficient k_{βw}) of the β-axis magnetic detection element 8β for the U-phase current line 6u (or the W-phase current line 6w) becomes the maximum value (or the minimum value), on the second virtual line L2, both of change directions of the magnetic sensitivity coefficient k_{βu} of the β-axis magnetic detection element 8ß for the U-phase current line 6u and the magnetic sensitivity coefficient k_{βw} of the β-axis magnetic detection element 8β for the W-phase current line 6w due to positional deviation of the β-axis magnetic detection element 8β along the first virtual line L1 are toward the 0 side. Therefore, according to the current detection apparatus 3, it is possible to improve toughness of the β-axis magnetic detection element 8β against positional deviation along the first virtual line L1 relative to the U-phase current line 6u and the W-phase current line 6w and, therefore, contribute to improvement of energy efficiency.
(3) In the present embodiment, the detection center of the α-axis magnetic detection element 8α is arranged within the α-axis element arrangement surface Pα that is orthogonal to the three phase current lines 6u, 6v, and 6w and is different from the β-axis element arrangement surface Pβ. Therefore, according to the present embodiment, it is possible to cause the output value S_{α} of the α-axis magnetic detection element 8α to be proportional to the α-phase current value I_{α} which is obtained by combining currents flowing through the three phase current lines 6u, 6v, and 6w at a determined ratio by the Clarke transformation. Further, in the present embodiment, the detection center of the β-axis magnetic detection element 8β is arranged within the β-axis element arrangement surface Pβ that is orthogonal to the U-phase current line 6u and the W-phase current line 6w and is different from the α-axis element arrangement surface Pα. Therefore, according to the present embodiment, it is possible to cause the output value S_{β} of the β-axis magnetic detection element 8β to be proportional to the β-phase current value I_{β} which is obtained by combining currents flowing through the U-phase current line 6u and the W-phase current line 6w at a determined ratio by the Clarke transformation and is orthogonal to the α-phase current value I_{α}.

### <Modification>

In the present embodiment, the description has been made on the case where the detection center of the β-axis magnetic detection element 8β is arranged within the β-phase element arrangement surface Pβ that is orthogonal to the two phase current lines 6u and 6w as shown in FIG. 4. The present invention, however, is not limited thereto.

The detection center of the β-axis magnetic detection element 8β may be arranged within a β-phase element arrangement surface Pβ′ that is orthogonal to the three phase current lines 6u, 6v, and 6w as shown in FIG. 6. In this case, it is preferable to arrange the V-phase current line 6v so as to intersect the β-axis element arrangement surface Pβ′ at the midpoint P0 of the first virtual line L1 that passes through the U-phase current line 6u and the W-phase current line 6w, arrange the detection center of the β-axis magnetic detection element 8β on the second virtual line L2 similarly to the example shown in FIG. 4, and arrange the detection axis Oβ of the β-axis magnetic detection element 8β orthogonal to the first virtual line L1. Thereby, it is possible to cause a magnetic field formed by a current flowing through the V-phase current line 6v and the detection axis Oβ of the β-axis magnetic detection element 8β to be orthogonal to each other, and, therefore, it is possible to cause the output value SB of the β-axis magnetic detection element 8β to be proportional to the β-phase current value Ip as shown by Formula (4) above.

Furthermore, similarly to the example shown in FIG. 4, it is preferable to set the second axial distance Dy between the β-axis magnetic detection element 8β and the U-phase current line 6u (or the W-phase current line 6w) within the range of the predetermined allowable setting error ±Δy with the first axial distance Dx between the β-axis magnetic detection element 8β and the U-phase current line 6u (or the W-phase current line 6w) as the center (Dx−Δy≤Dy≤Dx+Δy). In other words, it is preferable to arrange the detection center of the β-axis magnetic detection element 8 within the range of the allowable setting error ±Δy with such a position that the magnetic sensitivity coefficient k_{βu} (or the magnetic sensitivity coefficient k_{βw}) of the β-axis magnetic detection element 8β for the U-phase current line 6u (or the W-phase current line 6w) becomes the maximum value (or the minimum value) as the center on the second virtual line L2. Thereby, similarly to the example shown in FIG. 4, it is possible to improve the toughness of the β-axis magnetic detection element 8β against positional deviation.

Note that, in the case of providing the β-axis magnetic detection element 8β as shown in FIG. 6, when the detection center of the β-axis magnetic detection element 8β deviates from the second virtual line L2 along the direction orthogonal to the second virtual line L2, the output value S_{β} of the β-axis magnetic detection element 8β is influenced by a current flowing through the V-phase current line 6v. However, changes in the two magnetic sensitivity coefficients k_{βu} and k_{βw} due to the positional deviation is the same as the example shown in FIG. 4. Therefore, even in the case of arranging the detection center of the β-axis magnetic detection element 8β on the β-phase element arrangement surface Pβ′ shown in FIG. 6, it is possible to improve the toughness of the β-axis magnetic detection element 8β against positional deviation, similarly to the example shown in FIG. 4.

### Second Embodiment

Next, a description will be made below on a current detection apparatus according to a second embodiment of the present invention with reference to drawings. Note that, in the description below, the same components as the current detection apparatus 3 according to the first embodiment will be given the same reference signs, and detailed description thereof will be omitted. The current detection apparatus according to the present embodiment is different from the current detection apparatus 3 according to the first embodiment in the configuration of the sensor unit.

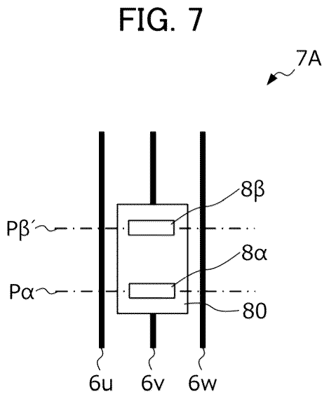

FIG. 7 is a diagram schematically showing the configuration of a sensor unit 7A according to the present embodiment. The sensor unit 7A includes the α-axis magnetic detection element 8α and the β-axis magnetic detection element 8β provided around the three phase current lines 6u, 6v, and 6w, and a board 80 to which the magnetic detection elements 8α and 8β are fixed. The detection center and detection axis of the α-axis magnetic detection element 8α are arranged within the α-axis element arrangement surface Pα in the aspect described with reference to FIG. 3, and the detection center and detection axis of the β-axis magnetic detection element 8β are arranged within the β-axis element arrangement surface Pβ′ in the aspect described with reference to FIG. 6. That is, the sensor unit 7A according to the present embodiment is different from the sensor unit 7 according to the first embodiment in that the α-axis magnetic detection element 8α and the β-axis magnetic detection element 8β are integrated by means of the board 80. Therefore, for example, if the detection center of the β-axis magnetic detection element 8β deviates from the second virtual line L2 toward the U-phase current line 6u side along the direction orthogonal to the second virtual line L2 by the distance dx as shown in FIG. 6, the α-axis magnetic detection element 8α also deviates toward the U-phase current line 6u side by the distance dx.

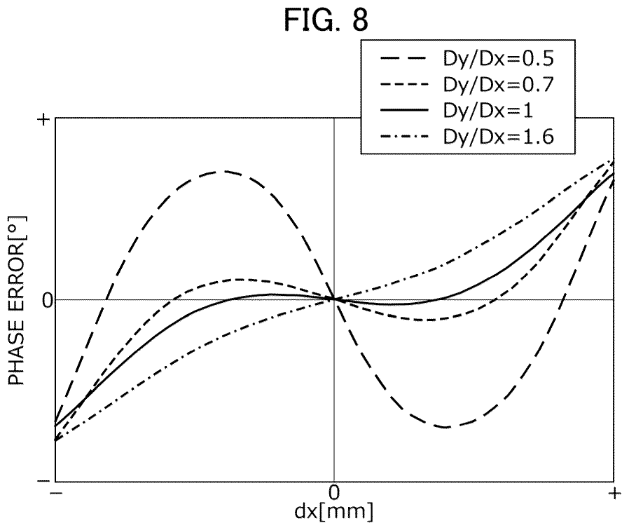

FIG. 8 is a diagram showing a relationship between the positional deviation amount (dx) of the detection centers of the two magnetic detection elements 8α and 8β and phase error between the output values S_{α} and S_{β} of the two magnetic detection elements 8α and 8β. Here, the phase error refers to an error of the phase difference (90°) between the output values S_{α} and S_{β} of the two magnetic detection elements 8α and 8β. Furthermore, FIG. 8 shows phase errors in the case of setting the ratio of the second axial distance Dy to the first axial distance Dx between the β-axis magnetic detection element 8 and the U-phase current line 6u (or the W-phase current line 6w) to “0.5”, “0.7”, “1”, and “1.6” with different line types.

As shown in FIG. 8, when the positional deviation amount of the detection centers of the two magnetic detection elements 8α and 8β is changed from 0, the phase difference between the output values S_{α} and S_{β} of the two magnetic detection elements 8α and 8β changes from 90°. The slope of the phase error near dx=0 decreases in order of “0.5”, “1.6”, “0.7”, and “1” of the ratio Dy/Dx. In other words, by causing the second axial distance Dy and the first axial distance Dx to be approximately equal, it is possible to minimize the slope of the phase error near dx=0. Therefore, by integrating the α-axis magnetic detection element 8α and the β-axis magnetic detection element 8β and, furthermore, setting the second axial distance Dy between the β-axis magnetic detection element 8β and the U-phase current line 6u (or the W-phase current line 6w) within the range of the predetermined allowable setting error ±Δy (Dx−Δy≤Dy≤Dx+Δy) with the first axial distance Dx between the β-axis magnetic detection element 8β and the U-phase current line 6u (or the W-phase current line 6w) as the center, it is possible to improve the toughness of the two magnetic detection elements 8α and 8β against positional deviation along the first virtual line L1. In other words, by integrating the α-axis magnetic detection element 8α and the β-axis magnetic detection element 8α and, furthermore, arranging the detection center of the β-axis magnetic detection element 8β within the range of the allowable setting error ±Δy with such a position that the magnetic sensitivity coefficient k_{βu} (or the magnetic sensitivity coefficient kw) of the β-axis magnetic detection element 8β for the U-phase current line 6u (or the W-phase current line 6w) becomes the maximum value (or the minimum value) as the center, on the second virtual line L2, it is possible to improve the toughness of the two magnetic detection elements 8α and 8β against positional deviation along the first virtual line L1.

According to the current detection apparatus according to the present embodiment, the following effect is obtained in addition to the above effects (1) to (3).

(4) In the present embodiment, by integrating the α-axis magnetic detection element 8α and the β-axis magnetic detection element 8β, it is possible to cause positional deviation amounts of the magnetic detection elements 8α and 8β relative to the phase current lines 6u, 6v, and 6w to be equal. Furthermore, as described above, in the state in which the magnetic detection elements 8α and 8β are integrated, the variation of the phase error between the output values S_{α} and S_{β} of the magnetic detection elements 8α and 8β due to positional deviation of the detection centers of the magnetic detection elements 8α and 8β along the first virtual line L1 is minimized when the second axial distance Dy and the first axial distance Dx between the detection centers of the magnetic detection elements 8α and 8β and the U-phase current line 6u (or the W-phase current line 6w) are set to be approximately equal. Therefore, according to the present embodiment, it is possible to improve the toughness of the magnetic detection elements 8α and 8β against positional deviation along the first virtual line L1 relative to the phase current lines 6u, 6v, and 6w.

Though one embodiment of the present invention has been described above, the present invention is not limited thereto. A detailed configuration may be appropriately changed within the spirit of the present invention.

What is claimed is:

1. A current detection apparatus for detecting currents flowing through a first phase current line, a second phase current line, and a third phase current line of a three-phase motor, the current detection apparatus comprising:
an α-axis magnetic detection element provided around the first, second, and third phase current lines; and
a β-axis magnetic detection element provided around the first and third phase current lines, wherein
a detection axis of the β-axis magnetic detection element is arranged orthogonal to a first virtual line connecting the first and third phase current lines, on a β-axis element arrangement surface that is orthogonal to both of the first and third phase current lines and includes a detection center of the β-axis magnetic detection element;
the detection center of the β-axis magnetic detection element is arranged on a second virtual line that is orthogonal to the first virtual line and passes through a midpoint of the first virtual line; and
a distance between the detection center of the β-axis magnetic detection element and the first phase current line along the second virtual line is within a predetermined allowable setting error range with a distance between the detection center of the β-axis magnetic detection element and the first phase current line along the first virtual line as a center.

2. The current detection apparatus according to claim 1, wherein a detection center of the α-axis magnetic detection element is arranged within an α-axis element arrangement surface that is orthogonal to the first, second, and third phase current lines and is different from the β-axis element arrangement surface.

3. The current detection apparatus according to claim 1, wherein the α-axis magnetic detection element and the β-axis magnetic detection element are integrated.

4. The current detection apparatus according to claim 2, wherein the α-axis magnetic detection element and the β-axis magnetic detection element are integrated.

5. A current detection apparatus for detecting currents flowing through a first phase current line, a second phase current line, and a third phase current line of a three-phase motor, the current detection apparatus comprising:
an α-axis magnetic detection element provided around the first, second, and third phase current lines; and
a β-axis magnetic detection element provided around the first and third phase current lines, wherein
a detection axis of the β-axis magnetic detection element is arranged orthogonal to a first virtual line connecting the first and third phase current lines, on a β-axis element arrangement surface that is orthogonal to both of the first and third phase current lines and includes a detection center of the β-axis magnetic detection element;
the detection center of the β-axis magnetic detection element is arranged within a predetermined allowable setting error range with such a position that a magnetic sensitivity coefficient of the β-axis magnetic detection element for the first phase current line becomes a maximum or minimum value as a center, on a second virtual line that is orthogonal to the first virtual line and passes through a midpoint of the first virtual line.

6. The current detection apparatus according to claim 5, wherein a detection center of the α-axis magnetic detection element is arranged within an α-axis element arrangement surface that is orthogonal to the first, second, and third phase current lines and is different from the β-axis element arrangement surface.

7. The current detection apparatus according to claim 5, wherein the α-axis magnetic detection element and the β-axis magnetic detection element are integrated.

8. The current detection apparatus according to claim 6, wherein the α-axis magnetic detection element and the β-axis magnetic detection element are integrated.
